(19) United States
(12) Patent Application Publication
(10) Pub. No.: US 2022/0231256 A1
(43) Pub. Date: Jul. 21, 2022

(54) DISPLAY APPARATUS AND MANUFACTURING THE SAME

(71) Applicant: SAMSUNG DISPLAY CO., LTD., Yongin-si (KR)

(72) Inventors: Jaeheung Ha, Yongin-si (KR); Jongwoo Kim, Yongin-si (KR); Changyeong Song, Yongin-si (KR); Yongchan Ju, Yongin-si (KR); Heeyeon Park, Yongin-si (KR); Hyein Yang, Yongin-si (KR); Woosuk Jung, Yongin-si (KR)

(21) Appl. No.: 17/404,336

(22) Filed: Aug. 17, 2021

(30) Foreign Application Priority Data
Jan. 21, 2021 (KR) 10-2021-0008792

(51) Int. Cl. H01L 51/52; H01L 51/56

(52) U.S. Cl. CPC H01L 51/5253; H01L 51/56; H01L 51/5259

(57) ABSTRACT

A display apparatus includes: a substrate including a display area and a peripheral area around the display area, a first organic layer arranged in the peripheral area, and a second organic layer arranged in the display area and the peripheral area. A tilt angle of a side surface of the second organic layer is equal to or greater than about 10 degrees and less than or equal to about 90 degrees.

This application claims priority to Korean Patent Application No. 10-2021-0008792, filed on Jan. 21, 2021, and all the benefits accruing therefrom under 35 U.S.C. § 119, the content of which in its entirety is herein incorporated by reference.

### BACKGROUND

### 1. Field

One or more embodiments relate to a display apparatus and a manufacturing method of the same.

### 2. Description of the Related Art

With the developments in the information society, demands for a display apparatus for displaying images increase in various forms. In a display apparatus field, a Flat Panel Display (“FPD”) apparatus has dramatically developed by replacing a cathode ray tube (“CRT”) having a large volume because the FPD is thin and light and has a great area. Examples of an FPD apparatus include a Liquid Crystal Display (“LCD”) apparatus, Plasma Display Panel (“PDP”), an Organic Light Emitting Display (“OLED”) apparatus, and an Electrophoretic Display (“EP”) apparatus.

Among the display apparatuses, an OLED apparatus may include an organic light-emitting diode including an opposite electrode, a pixel electrode, and an emission layer. When a voltage is applied to the opposite electrode and the pixel electrode of the organic light-emitting diode, visible rays are emitted from the emission layer.

The OLED apparatus may include organic light-emitting diodes emitting visible rays of red, green, and blue colors to realize a natural-color screen, and an emission layer of each organic light-emitting diode may be formed according to an inkjet printing manufacturing method, or the like.

Also, the display apparatus may have a display area, where images are produced, and a peripheral area, where no images are produced. Research has been actively conducted into an increase in a display area by decreasing an area of a peripheral area where wires, etc. of a display apparatus are arranged.

### SUMMARY

One or more embodiments include a display apparatus in which a size of a non-display area decreases, and a manufacturing method of the display apparatus.

Additional aspects will be set forth in part in the description which follows and, in part, will be apparent from the description, or may be learned by practice of the presented embodiments of the disclosure.

According to one or more embodiments, a display apparatus includes: a substrate including a display area and a peripheral area around the display area, a first organic layer arranged in the peripheral area, and a second organic layer arranged in the display area and the peripheral area, where a tilt angle of a side surface of the second organic layer is equal to or greater than about 10 degrees and less than or equal to about 90 degrees.

The first organic layer may directly contact the second organic layer in the peripheral area.

A shape of the first organic layer may be a hemisphere or an oval in a cross-sectional view.

The first organic layer may be arranged along a periphery of the display area.

The first organic layer may define an opening covering the display area in a plan view.

The second organic layer may overlap at least part of the opening in the plan view.

The first organic layer may be hydrophobic.

The display apparatus may further include a display element arranged in the display area, wherein the display element may include a pixel electrode and an opposite electrode.

The second organic layer may at least partially overlap the display element in the plan view.

The display apparatus may further include a first inorganic layer which covers the display element.

The first inorganic layer may be arranged under the first organic layer and the second organic layer.

The first organic layer may be arranged directly on the first inorganic layer.

The second organic layer may be arranged directly on the first inorganic layer.

The first inorganic layer may be hydrophilic.

The display apparatus may further include a second inorganic layer arranged on the first organic layer and the second organic layer.

The first inorganic layer may directly contact the second inorganic layer in the peripheral area.

According to one or more embodiments, there is provided a manufacturing method of a display apparatus including a substrate including a display area and a peripheral area around the display area. The manufacturing method includes: spreading a first organic material on the substrate in the peripheral area, forming a first organic layer by hardening the spread first organic material, spreading a second organic material on the substrate in the display area and the peripheral area, and forming a second organic layer by hardening the second organic material, where a tilt angle of a side surface of the second organic layer is equal to or greater than about 10 degrees and less than or equal to about 90 degrees.

A shape of the first organic layer may be a hemisphere or an oval in a cross-sectional view.

The first organic layer may directly contact the second organic layer.

The first organic layer may be formed along a periphery of the display area.

The first organic layer may define an opening including the display area therein in a plan view.

The second organic layer may overlap at least part of the opening in the plan view.

The first organic layer may be hydrophobic.

The manufacturing method may further include planarizing the spread second organic material after the spreading of the second organic material and before the hardening of the spread second organic material.

The manufacturing method may further include, before the spreading of the first organic material, forming a display element on the substrate, and forming a first inorganic layer on the display element.

The first inorganic layer may be hydrophilic.

The first organic layer may be formed directly on the first inorganic layer.

The second organic layer may be formed directly on the first inorganic layer.

The manufacturing method may further include forming a second inorganic layer on the first organic layer and the second organic layer.

The first inorganic layer may directly contact the second inorganic layer in the peripheral area.

Other aspects, features, and advantages other than those described above will become apparent from the following detailed description, claims and drawings for carrying out the invention.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to an embodiment;

FIGS. 2 and 3 are equivalent circuit diagrams of a pixel included in a display apparatus, according to an embodiment;

FIG. 4 is a schematic plan view of a display apparatus according to an embodiment;

FIG. 5 is a schematic cross-sectional view of a display apparatus according to an embodiment taken along line I-I′ of FIG. 4;

FIG. 6 is an enlarged view of a portion A of FIG. 5;

FIGS. 7 and 8 are schematic cross-sectional views of a display apparatus according to other embodiments;

FIG. 9 is a schematic cross-sectional view of a display apparatus according to another embodiment; and

FIGS. 10 to 15 are schematic cross-sectional views of a manufacturing method of a display apparatus, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. The attached drawings for illustrating preferred embodiments of the present disclosure are referred to in order to gain a sufficient understanding of the present disclosure, the merits thereof, and the aspects accomplished by the implementation of the present disclosure. The disclosure may, however, be embodied in many different forms and should not be construed as being limited to the embodiments set forth herein.

It will be understood that although the terms “first,” “second,” etc. may be used herein to describe various components, these components should not be limited by these terms. These components are only used to distinguish one component from another.

As used herein, the singular forms “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or component is referred to as being “formed on” another layer, region, or component, it can be formed directly or indirectly on the other layer, region, or component. That is, for example, intervening layers, regions, or components may be present.

Sizes of components in the drawings may be exaggerated for convenience of explanation. In other words, because sizes and thicknesses of components in the drawings are arbitrarily illustrated for convenience of explanation, the following embodiments are not limited thereto.

In the present specification, an expression such as “A and/or B” indicates A, B, or A and B. Also, an expression such as “at least one of A and B” indicates A, B, or A and B.

In embodiments described below, the description that lines extend “in a first direction or a second direction” includes that the lines extend in a straight line and includes that the lines extend in a zigzag shape or a curved line along a first direction or a second direction.

In embodiments below, when a component is referred to as being “on a plane,” it is understood that a component is viewed from the top (i.e., in a plan view), and when a component is referred to as being “on a cross-section,” it is understood that the component is vertically cut and viewed from the side (i.e., in a cross-sectional view). In embodiments below, when components “overlap” each other, the components overlap “on a plane” or “a cross-section.”

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value. Hereinafter, the embodiments of the disclosure will be described in detail with reference to the attached drawings, and like reference numerals in the drawings denote like reference elements.

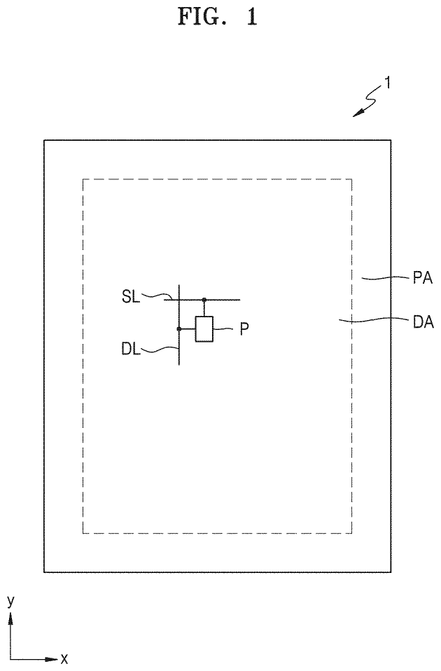

FIG. 1 is a schematic plan view of a display apparatus according to an embodiment.

Referring to FIG. 1, a display apparatus 1 may include a display area DA and a peripheral area PA around the display area DA. The peripheral area PA may surround at least part of the display area DA. Pixels P may be arranged in the display area DA. The display apparatus 1 may provide images by light emitted from the pixels P arranged in the display area DA, and the peripheral area PA may be a non-display area where no images are provided.

Hereinafter, the display apparatus 1 is an organic light-emitting display apparatus, but is not limited thereto. In another embodiment, the display apparatus 1 may be an inorganic light-emitting display (or an inorganic EL display) apparatus, a quantum-dot light-emitting display apparatus, or the like. For example, an emission layer of a display element included in the display apparatus 1 may include organic materials, inorganic materials, quantum dots, both organic materials and quantum dots, or both inorganic materials and quantum dots.

FIG. 1 illustrates the display apparatus 1 having a flat display surface, but one or more embodiments are not limited thereto. In an embodiment, the display apparatus 1 may include a cubic display surface or a curved display surface.

When the display apparatus 1 includes a cubic display surface, the display apparatus 1 may include display areas directed in different directions, for example, may include multifaceted cylindrical display surfaces. In an embodiment, when the display apparatus 1 includes a curved display surface, the display apparatus 1 may be flexible, foldable, rollable, or the like.

FIG. 1 illustrates the display apparatus 1 that may be applied to a mobile terminal. Although not illustrated, electronic modules, camera modules, power modules, or the like, which are embedded in a main board, are located in brackets, cases, or the like together with the display apparatus 1, thereby forming the mobile terminal. In particular, the display apparatus 1 may be applied to a large electronic apparatus such as a television or a monitor, a small- and medium-sized electronic apparatus such as a tablet computer, a navigation device of an automobile, a game device, or a smart watch, or the like.

FIG. 1 illustrates that the display apparatus 1 includes the display area DA that is rectangular, but a shape of the display area DA may vary, for example, a circle, an oval, or a polygon such as a triangle or a pentagon in a plan view.

The display apparatus 1 includes the pixels P arranged in the display area DA. Each pixel P in the display area DA may include an organic light-emitting diode OLED and may emit, for example, red light, green light, blue light, or white light from the organic light-emitting diode OLED. Each pixel P may be understood as a pixel emitting any one of red light, green light, blue light, and white light, as described above.

The pixels P may be electrically connected to scan lines SL extending in a first direction (e.g., an x direction) and data lines DL extending in a second direction (e.g., a y direction) crossing the first direction (e.g., the x direction), respectively. A scan signal may be provided to each pixel P through the scan line SL, and a data signal may be provided to each pixel P through the data line DL.

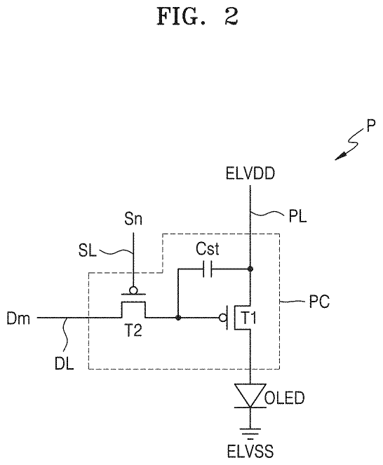

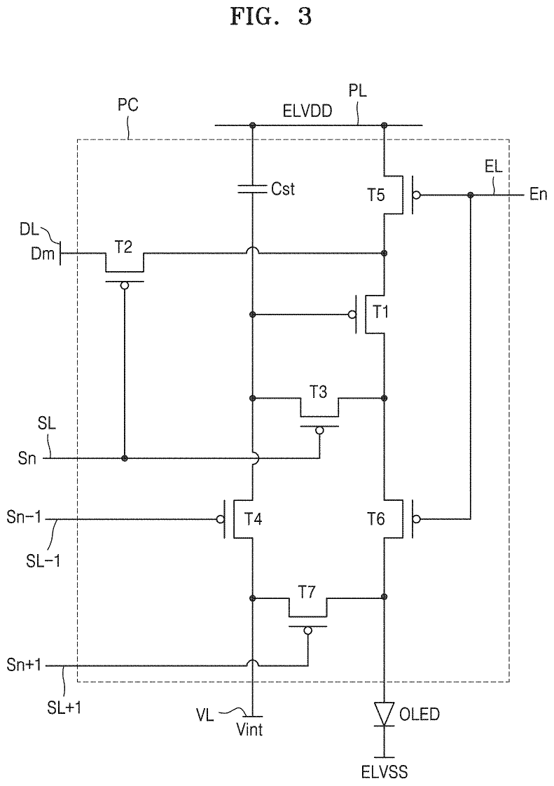

FIGS. 2 and 3 are equivalent circuit diagrams of a pixel included in a display apparatus, according to an embodiment.

Referring to FIG. 2, each pixel P may include a pixel circuit PC connected to the scan line SL and the data line DL, and the organic light-emitting diode OLED connected to the pixel circuit PC.

The pixel circuit PC may include a driving thin film transistor T1, a switching thin film transistor T2, and a storage capacitor Cst. The switching thin film transistor T2 may be connected to the scan line SL and the data line DL and may be configured to transmit a data signal Dm, which is input through the data line DL, to the driving thin film transistor T1 in response to a scan signal Sn input through the scan line SL.

The storage capacitor Cst may be connected to the switching thin film transistor T2 and a driving power line PL and may be configured to store a voltage corresponding to a difference between a voltage from the switching thin film transistor T2 and a power voltage ELVDD provided to the driving power line PL.

The driving thin film transistor T1 may be connected to the driving power line PL and the storage capacitor Cst and configured to control a driving current, which flows in the organic light-emitting diode OLED from the driving power line PL and corresponds to the voltage stored in the storage capacitor Cst. The organic light-emitting diode OLED may emit light having certain brightness, according to the driving current.

FIG. 2 illustrates that the pixel circuit PC includes two thin film transistors and one storage capacitor, but one or more embodiments are not limited thereto.

Referring to FIG. 3, the pixel circuit PC may include the driving thin film transistor T1, the switching thin film transistor T2, a compensation thin film transistor T3, a first initialization thin film transistor T4, a driving control thin film transistor T5, an emission control thin film transistor T6, and a second initialization thin film transistor T7.

FIG. 3 illustrates that each pixel circuit PC includes signal lines SL, SL−1, SL+1, EL, and DL, an initialization voltage line VL, and the driving power line PL, but one or more embodiments are not limited thereto. In an embodiment, at least any one of the signal lines SL, SL−1, SL+1, EL, and DL and/or the initialization voltage line VL may be shared by neighboring pixel circuits.

A drain electrode of the driving thin film transistor T1 may be electrically connected to the organic light-emitting died OLED via the emission control thin film transistor T6. The driving thin film transistor T1 may receive the data signal Dm and may be configured to deliver the driving current to the organic light-emitting died OLED, according to a switching operation of the switching thin film transistor T2.

A gate electrode of the switching thin film transistor T2 may be connected to the scan line SL, and a source electrode thereof may be connected to the data line DL. A drain electrode of the switching thin film transistor T2 may be connected to a source electrode of the driving thin film transistor T1 and the driving power line PL via the driving control thin film transistor T5.

The switching thin film transistor T2 may be turned on according to the scan signal Sn received through the scan line SL and may perform the switching operation of transmitting the data signal Dm, which is transmitted through the data line DL, to the source electrode of the driving thin film transistor T1.

A gate electrode of the compensation thin film transistor T3 may be connected to the scan line SL. A source electrode of the compensation thin film transistor T3 may be connected to the drain electrode of the driving thin film transistor T1 and the pixel electrode of the organic light-emitting diode OLED via the emission control thin film transistor T6. A drain electrode of the compensation thin film transistor T3 may be connected to any one of electrodes of the storage capacitor Cst, a source electrode of the first initialization thin film transistor T4, and the gate electrode of the driving thin film transistor T1. The compensation thin film transistor T3 may be turned on according to the scan signal Sn transmitted through the scan line SL and may connect the gate electrode of the driving thin film transistor T1 to the drain electrode of the driving thin film transistor T1, thus diode-connecting the driving thin film transistor T1.

A gate electrode of the initialization thin film transistor T4 may be connected to a previous scan line SL−1. A drain electrode of the initialization thin film transistor T4 may be connected to the initialization voltage line VL. The source electrode of the first initialization thin film transistor T4 may be connected to any one of the electrodes of the storage capacitor Cst, a drain electrode of the compensation thin film transistor T3 and the gate electrode of the driving thin film transistor T1. The first initialization thin film transistor T4 may be turned on according to the previous scan signal Sn-1 transmitted through the previous scan line SL−1 and may be configured to deliver an initialization voltage Vint to the gate electrode of the driving thin film transistor T1, thus performing an initialization operation of initializing a voltage of the gate electrode of the driving thin film transistor T1.

A gate electrode of the driving control thin film transistor T5 may be connected to an emission control line EL. A source electrode of the driving control thin film transistor T5 may be connected to the driving power line PL. A drain electrode of the driving control thin film transistor T5 may be connected to the source electrode of the driving thin film transistor T1 and the drain electrode of the switching thin film transistor T2.

A gate electrode of the emission control thin film transistor T6 may be connected to the emission control line EL. A source electrode of the emission control thin film transistor T6 may be connected to the drain electrode of the driving thin film transistor T1 and the source electrode of the compensation thin film transistor T3. A drain electrode of the emission control thin film transistor T6 may be electrically connected to a pixel electrode of the organic light-emitting diode OLED. The driving control thin film transistor T5 and the emission control thin film transistor T6 are simultaneously turned on according to the emission control signal En transmitted through the emission control line EL and may be configured to deliver the driving voltage ELVDD to the organic light-emitting diode OLED, thereby allowing a driving current to flow in the organic light-emitting diode OLED.

A gate electrode of the second initialization thin film transistor T7 may be connected to a next scan line SL+1. A source electrode of the second initialization thin film transistor T7 may be connected to the pixel electrode of the organic light-emitting diode OLED. A drain electrode of the second initialization thin film transistor T7 may be connected to the initialization voltage line VL. The second initialization thin film transistor T7 may be turned on according to a next scan signal Sn+1 transmitted through the next scan line SL+1 and may be configured to initialize the pixel electrode of the organic light-emitting diode OLED.

FIG. 3 illustrates that the first initialization thin film transistor T4 and the second initialization thin film transistor T7 are connected to the previous scan line SL−1 and the next scan line SL+1, respectively. However, one or more embodiments are not limited thereto. In an embodiment, both the first initialization thin film transistor T4 and the second initialization thin film transistor T7 may be connected to the previous scan line SL−1 and may be driven according to the previous scan line SL−1.

Another electrode of the storage capacitor Cst may be connected to the driving power line PL. Any one of the electrodes of the storage capacitor Cst may be connected to the gate electrode of the driving thin film transistor T1, the drain electrode of the compensation thin film transistor T3, and the source electrode of the first initialization thin film transistor T4.

A common voltage ELVSS may be applied to an opposite electrode (e.g., a cathode) of the organic light-emitting diode OLED. The organic light-emitting diode OLED may receive the driving current from the driving thin film transistor T1 and emit light.

The pixel circuit PC is not limited to the number of thin film transistors, the number of storage capacitors, and a circuit design described with reference to FIGS. 2 and 3, and the numbers and the circuit design may vary.

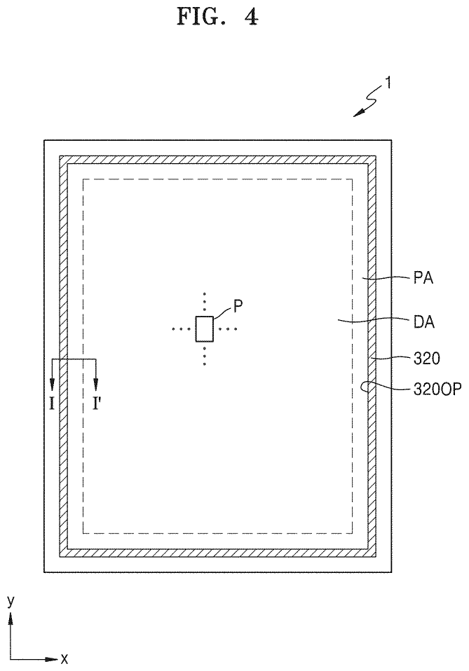

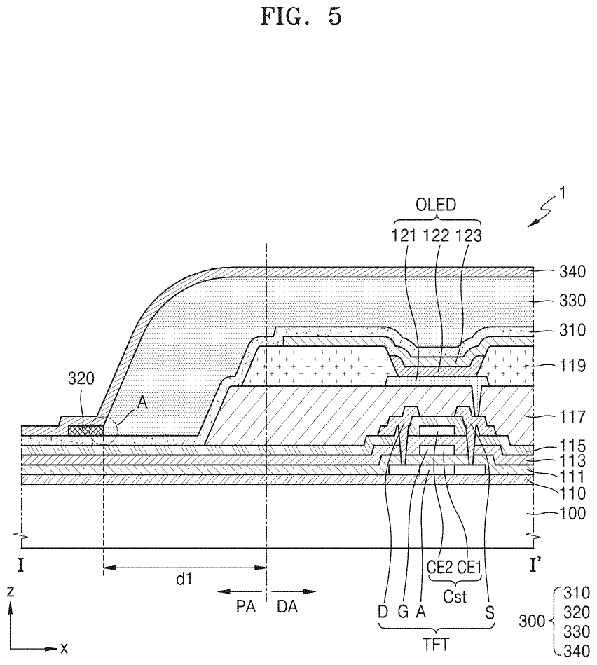

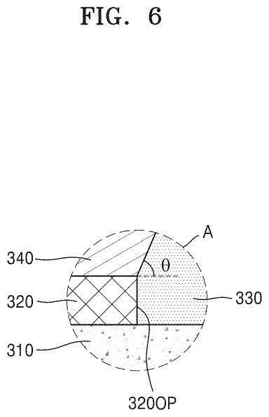

FIG. 4 is a schematic plan view of a display apparatus according to an embodiment, FIG. 5 is a schematic cross-sectional view of a display apparatus according to an embodiment taken along line I-I′ of FIG. 4, and FIG. 6 is an enlarged view of a portion A of FIG. 5.

Referring to FIG. 4, the display apparatus 1 may include the display area DA and the peripheral area PA around the display area DA. In the display area DA, the pixels P may be arranged.

In an embodiment, a first organic layer 320 may be arranged in the peripheral area PA. On a plane (i.e., in a plan view), the first organic layer 320 may be spaced apart from the display area DA by a certain distance, and the first organic layer 320 may be arranged along a periphery of the display area DA. That is, in the plan view, the first organic layer 320 may have a rectangular ring shape. The first organic layer 320 may surround an outer side of the display area DA. The first organic layer 320 may define an opening 320OP covering the display area DA in a plan view. In the opening 320OP defined in the first organic layer 320, a second organic layer 330 (of FIG. 5) may be arranged. Detailed descriptions thereof will be provided below with reference to FIG. 5.

Hereinafter, a stack structure of components of the display apparatus 1 will be described.

Referring to FIG. 5, the display apparatus 1 may include a substrate 100. In an embodiment, the display apparatus 1 may include the display area DA and the peripheral area PA around the display area DA. In this case, it may be understood that the substrate 100 of the display apparatus 1 includes the display area DA and the peripheral area PA around the display area DA.

In an embodiment, a thin film transistor TFT and a display element (e.g., the organic light-emitting diode OLED) may be arranged in the display area DA of the substrate 100. In an embodiment, the thin film transistor TFT and the display element (e.g., the organic light-emitting diode OLED) may be electrically connected to each other.

The substrate 100 may include glass or polymer resin. The polymer resin may include at least one selected from among the group consisting of polyether sulfone, polyacrylate, polyetherimide, polyethylene naphthalate, polyethylene terephthalate, polyphenylene sulfide, polyarylate, polyimide, polycarbonate, cellulose acetate propionate, and poly(arylene ether sulfone). The substrate 100 may have a multilayered structure including a layer including the polymer resin and an inorganic layer (not illustrated).

In an embodiment, the substrate 100 may be a flexible substrate that is, for example, bendable, foldable, rollable, or the like.

A buffer layer 110 may be arranged on the substrate 100. The buffer layer 110 may be on the substrate 100, may decrease or prevent the penetration of foreign materials, moisture, or external air from the bottom of the substrate 100 and may provide a flat upper surface on an upper surface of the substrate 100. The buffer layer 110 may include an inorganic material such as oxide or nitride, an organic material, or a composite of organic/inorganic materials and may have a single-layer structure or a multilayered structure including an inorganic material and an organic material. In detail, the buffer layer 110 may include at least one inorganic insulating material selected from the group consisting of silicon oxide (SiO₂), silicon nitride (SiNₓ), silicon oxynitride (SiO_{X}N_{Y}), aluminum oxide (Al₂O₃), titanium oxide (TiO₂), tantalum oxide (Ta₂O₅), hafnium oxide (HfO₂), and zinc oxide (ZnO). A barrier layer (not illustrated) may be further included between the substrate 100 and the buffer layer 110, the barrier layer preventing the penetration of external air.

The thin film transistor TFT may be arranged on the buffer layer 110. The thin film transistor TFT may include a semiconductor layer A, a gate electrode G, a source electrode S, and a drain electrode D.

The semiconductor layer A may be arranged on the buffer layer 110. In an embodiment, the semiconductor layer A may include an oxide semiconductor or a silicon semiconductor. In an embodiment, when the semiconductor layer A includes an oxide semiconductor, the semiconductor layer A may include at least one oxide selected from the group consisting of indium (In), gallium (Ga), tin (Sn), zirconium (Zr), vanadium (V), hafnium (Hf), cadmium (Cd), germanium (Ge), chromium (Cr), titanium (Ti), and zinc (Zn). For example, the semiconductor layer A may include InSnZnO (“ITZO”), InGaZnO (“IGZO”), or the like. In an embodiment, when the semiconductor layer A includes a silicon semiconductor, the semiconductor layer A may include amorphous silicon (a-Si) or Low Temperature Poly-Silicon (“LTPS”) produced by crystallizing a-Si.

In an embodiment, the semiconductor layer A may include a channel area overlapping the gate electrode G in a plan view and source and drain areas on opposite sides of the channel area. The source and drain areas may include impurities having higher concentrations than the centration of impurities in the channel area. Here, the impurities may include N-type impurities or P-type impurities. The source area and the drain area may be understood as the source electrode S and the drain electrode D of the thin film transistor TFT, respectively.

A first insulating layer 111 may be arranged on the semiconductor layer A. The first insulating layer 111 may include at least one inorganic insulating material selected from the group consisting of SiO₂, SiNₓ, SiO_{X}N_{Y}, Al₂O₃, TiO₂, Ta₂O₅, HfO₂, and ZnO. In an embodiment, the first insulating layer 111 may be a layer or layers including the above inorganic insulating material(s).

The gate electrode G may be arranged on the first insulating layer 111. At least some portions of the gate electrode G may overlap the semiconductor layer A thereunder in a plan view. The gate electrode G may include at least one metal selected from the group consisting of Al, Pt, Pd, Ag, Mg, Au, Ni, Nd, Ir, Cr, Li, Ca, Mo, Ti, W, and/or Cu and may be a single layer or layers including the above material(s). The gate electrode G may be connected to a gate line through which an electrical signal is transmitted to the gate electrode G.

A second insulating layer 113 may be arranged on the gate electrode G. The second insulating layer 113 may include at least one inorganic insulating material selected from the group consisting of SiO₂, SiNₓ, SiO_{X}N_{Y}, Al₂O₃, TiO₂, Ta₂O₅, HfO₂, and ZnO. In an embodiment, the second insulating layer 113 may be a layer or layers including the above inorganic insulating material(s).

The storage capacitor Cst may be arranged on the first insulating layer 111. The storage capacitor Cst may include a lower electrode CE1 and an upper electrode CE2 overlapping the lower electrode CE1 in a plan view.

The lower electrode CE1 may be arranged on the first insulating layer 111. In an embodiment, the gate electrode G of the thin film transistor TFT may be the lower electrode CE1 of the storage capacitor Cst. That is, the lower electrode CE1 of the storage capacitor Cst may be integrated with the gate electrode G of the thin film transistor TFT. In an embodiment, the lower electrode CE1 of the storage capacitor Cst may be on the first insulating layer 111 as a component separated from the gate electrode G of the thin film transistor TFT.

The second insulating layer 113 may be arranged on the lower electrode CE1, and the upper electrode CE2 may be arranged on the second insulating layer 113. In an embodiment, at least some portions of the upper electrode CE2 may overlap the lower electrode CE1 thereunder. In an embodiment, the lower electrode CE1 and the upper electrode CE2 may at least partially overlap each other with the second insulating layer 113 therebetween in a plan view.

The upper electrode CE2 may include Al, Pt, Pd, Ag, Mg, Au, Ni, Nd, Ir, Cr, Ca, Mo, Ti, W, and/or Cu and may be a layer or layers including the above material(s).

A third insulating layer 115 may be arranged on the storage capacitor Cst. The third insulating layer 115 may include at least one inorganic insulating material selected from the group consisting of SiO₂, SiNₛ, SiO_{X}N_{Y}, Al₂O₃, TiO₂, Ta₂O₅, HfO₂, or ZnO. In an embodiment, the third insulating layer 115 may be a layer or layers including the above inorganic insulating material(s).

The source electrode S and the drain electrode D may be arranged on the third insulating layer 115. In an embodiment, the source electrode S and/or the drain electrode D may be electrically connected to the source area and/or the drain area thereunder, respectively, through a contact hole. The source electrode S and the drain electrode D may each include a conductive material such as Mo, Al, Cu, or Ti and may be a layer or layers including the above material(s). In an embodiment, the source electrode S and the drain electrode D may each have a multilayered structure of Ti/Al/Ti.

A planarization layer 117 may be arranged on the source electrode S and the drain electrode D. In an embodiment, the planarization layer 117 may be arranged in the display area DA, but at least part of the planarization layer 117 may extend to the peripheral area PA. In an embodiment, a side surface of the planarization layer 117 may be arranged in the peripheral area PA.

In an embodiment, the planarization layer 117 may include an organic material or an inorganic material and may be a layer or layers. In an embodiment, the planarization layer 117 may include general-purpose polymer such as benzocyclobutene (“BCB”), polyimide (“PI”), hexamethyldisiloxane (“HMDSO”), polymethylmethacrylate (“PMMA”) or polystyrene (“PS”), a polymer derivative having a phenol-based group, an acryl-based polymer, an imide-based polymer, an aryl-ether-based polymer, an amide-based polymer, a fluorine-based polymer, a p-xylene-based polymer, a vinyl alcohol-based polymer, and a blend thereof. Alternatively, in an embodiment, the planarization layer 117 may include SiO₂, SiNₓ, SiO_{X}N_{Y}, Al₂O₃, TiO₂, Ta₂O₅, HfO₂, ZnO, or the like. After the planarization layer 117 is formed, mechanochemical polishing may be performed to provide a planar upper surface.

In an embodiment, although not illustrated, the planarization layer 117 may include a first planarization layer and a second planarization layer. In an embodiment, the first planarization layer and the second planarization layer may include the same material. In an embodiment, the first planarization layer and the second planarization layer may include different materials.

In an embodiment, the display element may be disposed on the planarization layer 117. In an embodiment, the display element may be the organic light-emitting diode OLED. The display element (e.g., the organic light-emitting diode OLED) may include a pixel electrode 121, an emission layer 122, and an opposite electrode 123.

In an embodiment, the pixel electrode 121 may be arranged on the planarization layer 117. The pixel electrode 121 may be a (semi-transmissive) light-transmissive electrode or a reflection electrode. The pixel electrode 121 may include a reflection layer including Al, Pt, Pd, Ag, Mg, Au, Ni, Nd, Ir, Cr, Li, Ca, Mo, Ti, W, Cu, and a combination thereof, and a transparent or translucent electrode layer formed on the reflection layer. The transparent or translucent electrode layer may include at least one material selected from the group consisting of indium tin oxide (“ITO”), indium zinc oxide (“IZO”), zinc oxide (ZnO), indium oxide (In2O3), indium gallium oxide (“IGO”), and aluminum zinc oxide (“AZO”). The pixel electrode 121 may have a stack structure of ITO/Ag/ITO.

A pixel-defining layer 119 may be arranged on the planarization layer 117. In an embodiment, the pixel-defining layer 119 may be arranged in the display area DA, and at least part of the pixel-defining layer 119 may extend to the peripheral area PA. In an embodiment, a side surface of the pixel-defining layer 119 may be arranged in the peripheral area PA.

In an embodiment, the pixel-defining layer 119 may define an opening through which at least part of the pixel electrode 121 is exposed. An area exposed by the opening in the pixel-defining layer 119 may be defined as an emission area. Also, peripheral regions of the emission area may be a non-emission area, and the non-emission area may surround at least part of the emission area. That is, the display area DA may include emission areas and non-emission areas surrounding the emission areas.

The pixel-defining layer 119 may prevent arcs, etc. from being generated at edges of the pixel electrode 121 by increasing a distance between the pixel electrode 121 and the opposite electrode 123 above the pixel electrode 121. The pixel-defining layer 119 may include an organic insulating material such as PI, polyamide, acryl resin, BCB, HMDSO, or phenol resin and may be formed according to a spin coating method, etc. In an embodiment, a spacer (not illustrated) for preventing an indentation by a mask may be further arranged on the pixel-defining layer 119.

The emission layer 122 may be arranged on the pixel electrode 121 having at least a portion exposed by the pixel-defining layer 119. Although not illustrated, a first functional layer and a second functional layer may be selectively arranged on and under the emission layer 122.

In an embodiment, the first functional layer may be arranged under the emission layer 122, and the second functional layer may be arranged on the emission layer 122. The first functional layer and the second functional layer arranged on and under the emission layer 122 may be collectively referred to as organic functional layers.

The first functional layer may include a hole transport layer (“HTL”) and/or a hole injection layer (“HIL”), and the second functional layer may include an electron transport layer (“ETL”) and/or an electron injection layer (“EIL”).

The emission layer 122 may include an organic material including a fluorescent or phosphorescent material emitting red light, green light, blue light or white light. The emission layer 122 may include a low-molecular weight or a high-molecular weight organic material.

When the emission layer 122 includes a low-molecular weight organic material, an intermediate layer may have a single structure or a complex structure in which the HIL, the HTL, the emission layer 122, the ETL, the EIL, or the like are stacked, and may include various organic materials including copper phthalocyanine (CuPu), N,N′-Di(napthalene-1-yl)-N,N′-diphenyl-benzidine (“NPB”), (tris-8-hydroxyquinoline aluminum)(Alq₃), or the like.

When the emission layer 122 includes a high-molecular weight organic material, the intermediate layer may usually have a structure including the HTL and the emission layer 122. In this case, the HTL may include PEDOT, and the emission layer 122 may include Poly-Phenylene vinylene (“PPV”)-based polymer, polyfluorene polymer, or the like. The emission layer 122 may be formed according to a screen print or inkjet print method, a Laser Induced Thermal Imaging (“LITI”) method, or the like.

The opposite electrode 123 may be arranged on the emission layer 122. The opposite electrode 123 may be arranged on the emission layer 122 and cover the entire emission layer 122. The opposite electrode 123 may be in the display area DA and entirely cover the same. That is, the opposite electrode 123 may be integrally formed to entirely cover the pixels P arranged in the display area DA by using an open mask.

The opposite electrode 123 may include a conductive material having a low work function. For example, the opposite electrode 123 may include a transparent or translucent electrode including Ag, Mg, Al, Pt, Pd, Au, Ni, Nd, Ir, Cr, Li, Ca, or an alloy thereof. Alternatively, the opposite electrode 123 may further include a layer such as ITO, IZO, ZnO, or In₂O₃, on the transparent or translucent electrode including the above material.

In an embodiment, a thin film encapsulation layer 300 may be arranged on the organic light-emitting diode OLED. The thin film encapsulation layer 300 may include at least one organic layer and at least one inorganic layer. In an embodiment, the thin film encapsulation layer 300 may include a first inorganic layer 310, a first organic layer 320, a second organic layer 330, and a second inorganic layer 340.

In an embodiment, the first inorganic layer 310 may be arranged on the opposite electrode 123. In an embodiment, the first inorganic layer 310 may be in the display area DA and the peripheral area PA. In an embodiment, the first inorganic layer 310 may cover a side surface of the planarization layer 117 and a side surface of the pixel-defining layer 119 that are arranged in the peripheral area PA.

The first inorganic layer 310 may include at least one inorganic insulating material selected from the group consisting of SiO₂, SiNₓ, SiO_{X}N_{Y}, Al₂O₃, TiO₂, Ta₂O₅, HfO₂, and ZnO.

The first inorganic layer 310 may be hydrophilic. Because the first inorganic layer 310 is hydrophilic, the spreadability of an organic material of the second organic layer 330 described below may be improved. Thus, a thickness dispersion of the second organic layer 330 may decrease, and the second organic layer 330 may have a planar upper surface. That is, a flatness of the second organic layer 330 may be improved. In this case, the term “hydrophilic” indicates that a material is mixed well with water molecules. Here, the thickness is measured in a third direction (i.e., z direction) which is perpendicular to the first direction (i.e., x direction) and the second direction (i.e., y direction).

In an embodiment, the first organic layer 320 may be arranged on the first inorganic layer 310. In detail, the first organic layer 320 may be directly on the first inorganic layer 310. The first organic layer 320 may include a polymer-based material. The polymer-based material may include silicon-based resin, acryl-based resin, epoxy-based resin, PI, polyethylene, or the like. In an embodiment, the first organic layer 320 may not overlap the planarization layer 117 and/or the pixel-defining layer 119 in a plan view.

In an embodiment, the first organic layer 320 may be arranged in the peripheral area PA. As describe above with reference to FIG. 4, the first organic layer 320 may be arranged in the peripheral area PA along the periphery of the display area DA. In an embodiment, the first organic layer 320 may define the opening 320OP including the display area DA in a plan view.

In an embodiment, the first organic layer 320 may be hydrophobic. In this case, the term “hydrophobic” indicates that a material does not tend to be mixed well with water molecules (i.e., characteristics of the material).

In the peripheral area PA of the display apparatus 1, a dam for preventing a loss of the organic material forming the second organic layer 330 may be arranged. The dam in the peripheral area PA may include the same material as the planarization layer 117 and/or the pixel-defining layer 119 through the same processes as the planarization layer 117 and/or the pixel-defining layer 119. Because a process of forming the thin film encapsulation layer 300 is performed after a process of forming the planarization layer 117 and/or the pixel-defining layer 119 is performed, the first inorganic layer 310 may be formed on the dam. After the formation of the first inorganic layer 310, the organic material forming the second organic layer 330 may be spread. Because the organic material forming the second organic layer 330 may be spread after the first inorganic layer 310 is formed on the dam, the dam in the peripheral area PA may be spaced apart from the display area DA by a certain distance to prevent the loss of the organic material forming the second organic layer 330. In this case, a minimum distance from the display area DA to the dam in the peripheral area PA may be equal to or greater than about 470 micrometers (μm). Therefore, the dam in the peripheral area PA has to be separated from the display area DA by a certain distance or more, a size of the peripheral area PA (e.g., the non-display area) may increase. In this case, multiple dams may be arranged in the peripheral area PA.

In an embodiment, the first organic layer 320 may be hydrophobic, and the organic material forming the second organic layer 330 may be hydrophilic. Therefore, because the hydrophobic first organic layer 320 is arranged in the peripheral area PA along the periphery of the display area DA, the loss of the organic material forming the second organic layer 330 to the outside of the first organic layer 320 may decrease or may be effectively prevented. In detail, the first organic layer 320 may be hydrophobic, the organic material forming the second organic layer 330 may be hydrophilic, and the first organic layer 320 may be arranged in the peripheral area PA along the periphery of the display area DA. Thus, the spreadability of the hydrophilic organic material forming the second organic layer 330 may be restricted by the hydrophobic first organic layer 320 during the formation of the second organic layer 330, and the overflow of the organic material forming the second organic layer 330 to the outside of the first organic layer 320 may be effectively prevented or decrease.

In an embodiment, the distance between the first organic layer 320 and the display area DA may be less than the distance between the dam and the display area DA. In detail, the first organic layer 320 in the peripheral area PA may be spaced apart from the display area DA by a first distance d1. In this case, the first distance d1 may be a distance from an end portion of the first organic layer 320, which is adjacent to the display area DA, to the display area A, which is closest to the first organic layer 320. That is, the first distance d1 may be a minimum distance between the first organic layer 320 and the display area DA.

In an embodiment, the first distance d1, which is the minimum distance between the end portion of the first organic layer 320 and the display area DA, may be less than or equal to about 470 μm. Therefore, because the first distance d1, which is the minimum distance between the end portion of the first organic layer 320 and the display area DA, may be less than or equal to about 470 μm, the size of the peripheral area PA (e.g., the non-display area) may decrease.

Also, in an embodiment, because the first organic layer 320 functions as the dam for preventing or decreasing the loss of the organic material forming the second organic layer 330, the dam may not be arranged in the peripheral area PA. The size of the peripheral area PA may decrease because the dam is not arranged in the peripheral area PA, and thus, a full-screen display apparatus may be realized. (i.e., the peripheral area PA may not be seen substantially to a user in a plan view)

In an embodiment, the second organic layer 330 may be arranged on the first inorganic layer 310. In detail, the second organic layer 330 may be directly on the first inorganic layer 310. In detail, the second organic layer 330 may be arranged in the display area DA. The second organic layer 330 in the display area DA may at least partially overlap the display element (e.g., the organic light-emitting diode OLED) in a plan view.

In an embodiment, the second organic layer 330 may be arranged in the display area DA, and at least part of the second organic layer 330 may also be arranged in the peripheral area PA. In an embodiment, the second organic layer 330 may directly contact the first organic layer 320 in the peripheral area PA. In an embodiment, the second organic layer 330 may directly contact a side surface of the first organic layer 320. Alternatively, the second organic layer 330 may directly contact the side surface and at least part of an upper surface of the first organic layer 320.

In an embodiment, the second organic layer 330 may be arranged in the opening 320OP defined in the first organic layer 320. In an embodiment, the second organic layer 330 may overlap at least part of the opening 320OP defined in the first organic layer 320. In an embodiment, the second organic layer 330 may at least partially overlap the first organic layer 320 in a plan view.

Referring to FIGS. 5 and 6, in an embodiment, the side surface of the second organic layer 330 may be tilted at a certain degree. In an embodiment, the side surface of the second organic layer 330 may have a tilt angle θ that is equal to or greater than about 10 degrees and less than and equal to about 90 degrees.

In an embodiment, when an edge of the second organic layer 330 is on the upper surface of the first organic layer 320, the tilt angle θ of the side surface of the second organic layer 330 may be an angle (or a tilt angle) formed by the upper surface of the first organic layer 320 and the edge of the second organic layer 330.

In an embodiment, when the edge of the second organic layer 330 is on the side surface of the first organic layer 320, the tilt angle θ of the side surface of the second organic layer 330 may be an angle (or a tilt angle) formed by the edge of the second organic layer 330 and the upper surface of the first organic layer 320 or a major surface plane parallel to the upper surface of the substrate 100, which is defined by the first direction (i.e., x direction) and the second direction (i.e., y direction).

In an embodiment, when the edge of the second organic layer 330 is on the upper surface of the first organic layer 320, the tilt angle θ of the side surface of the second organic layer 330 may be an angle (or a tilt angle) formed by an upper surface of the first inorganic layer 310 and the edge of the second organic layer 330.

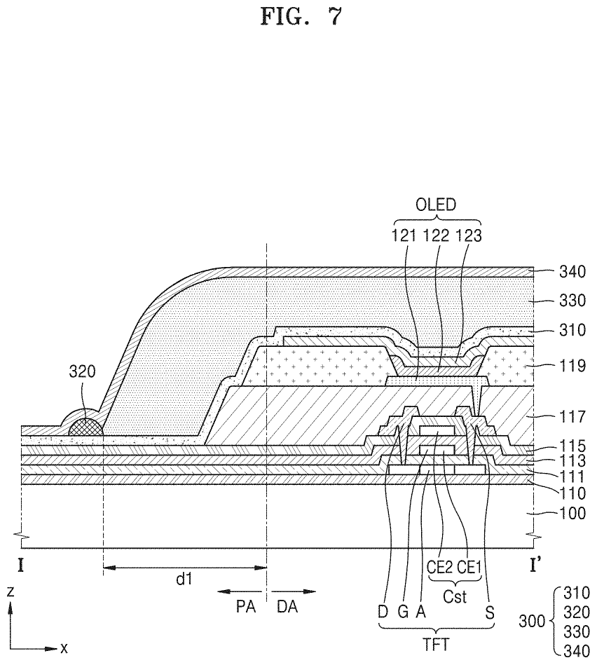

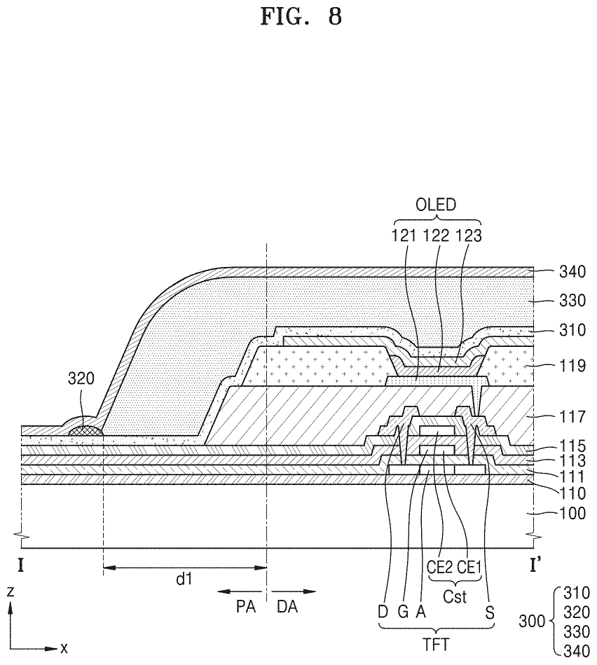

In an embodiment as described below with reference to FIGS. 7 and 8, when a shape of the first organic layer 320 is a hemisphere or an oval in a cross-sectional view, the tilt angle θ of the side surface of the second organic layer 330 may be an angle (or a tilt angle) formed by the edge of the second organic layer 330 and the major surface plane parallel to the upper surface of the substrate 100.

When the tilt angle θ of the side surface of the second organic layer 330 is less than about 10 degrees, the tilt angle θ of the side surface of the second organic layer 330 is too small, and thus, the distance (e.g., the first distance d1) between the first organic layer 320 and the display area DA in a plan view may increase so that the size of the peripheral area PA may increase. In this case, because the peripheral area PA corresponds to the non-display area, an increase in the size of the peripheral area PA may indicate that a size of the non-display area increases. On the contrary, when the tilt angle θ of the side surface of the second organic layer 330 is greater than 90 degrees, the second inorganic layer 340 arranged on the second organic layer 330 may be disconnected, and thus, the display element (e.g., the organic light-emitting died OLED) may be exposed to and damaged by foreign materials or moisture. Therefore, in an embodiment, because the tilt angle θ of the side surface of the second organic layer 330 between the first organic layer 320 and the second organic layer 330 is equal to or greater than about 10 degrees and less than or equal to about 90 degrees, the distance (e.g., the first distance d1) between the first organic layer 320 and the display area DA may decrease, and thus, a full-screen display apparatus may be realized (i.e., the peripheral area PA may not be seen substantially to a user in a plan view). At the same time, the damage of the display element (e.g., the organic light-emitting diode OLED) by foreign materials or moisture may be effectively prevented or reduced.

Referring back to FIG. 5, the second organic layer 330 may include a polymer-based material. The polymer-based material may include silicon-based resin, acryl-based resin, epoxy-based resin, PI, polyethylene, or the like. In an embodiment, the second organic layer 330 may include the same material as the first organic layer 320. In an embodiment, the second organic layer 330 may include a different material from the first organic layer 320.

In an embodiment, the second inorganic layer 340 may be arranged on the first organic layer 320 and the second organic layer 330. In detail, the second inorganic layer 340 may be arranged directly on the first organic layer 320 and the second organic layer 330. In an embodiment, the second inorganic layer 340 may be arranged in the display area DA and the peripheral area PA.

In an embodiment, because the first organic layer 320 functions as the dam for preventing or decreasing the loss of the organic material forming the second organic layer 330, the dam may not be arranged in the peripheral area PA. Therefore, the second inorganic layer 340 may cover a portion, in which the first organic layer 320 contacts the second organic layer 330, and may be arranged on the first organic layer 320 and the second organic layer 330.

In an embodiment, the first organic layer 320 may directly contact the second organic layer 330, the first organic layer 320 may directly contact the second inorganic layer 340, and the second organic layer 330 may directly contact the second inorganic layer 340. In an embodiment, the second inorganic layer 340 may be arranged directly on the portion in which the first organic layer 320 directly contacts the second organic layer 330.

In an embodiment, the first inorganic layer 310 and the second inorganic layer 340 may surround organic layers (e.g., the first organic layer 320 and the second organic layer 330). In an embodiment, the first inorganic layer 310 and the second inorganic layer 340 may directly contact each other in the peripheral area PA.

The second inorganic layer 340 may include at least one inorganic insulating material selected from the group consisting of SiO₂, SiNₓ, SiO_{X}N_{Y}, Al₂O₃, TiO₂, Ta₂O₅, HfO₂, and ZnO.

FIGS. 7 and 8 are schematic cross-sectional views of a display apparatus according to an embodiment. The embodiments of FIGS. 7 and 8 are different from the embodiment of FIG. 5 in that shapes of the first organic layer 320 in a cross-sectional view are a hemisphere and an oval, respectively. In FIGS. 7 and 8, the same reference numerals as those in FIG. 5 denote like elements, and descriptions thereof will not be repeated.

Referring to FIG. 5, in an embodiment, the shape of first organic layer 320 may be a rectangle. However, one or more embodiments are not limited thereto. For example, the shape of the first organic layer 320 may vary, for example, may be a square, a trapezoid, or the like.

Also, as illustrated in FIG. 7, the shape of the first organic layer 320 may be a hemisphere, and as illustrated in FIG. 8, the shape of the first organic layer 320 may be an oval.

In an embodiment, uneven portions may be formed on a surface of the first organic layer 320. As the uneven portions are formed on the surface of the first organic layer 320, the overflow of the organic material forming the second organic layer 330 to the outside of the first organic layer 320 may be effectively prevented or reduced.

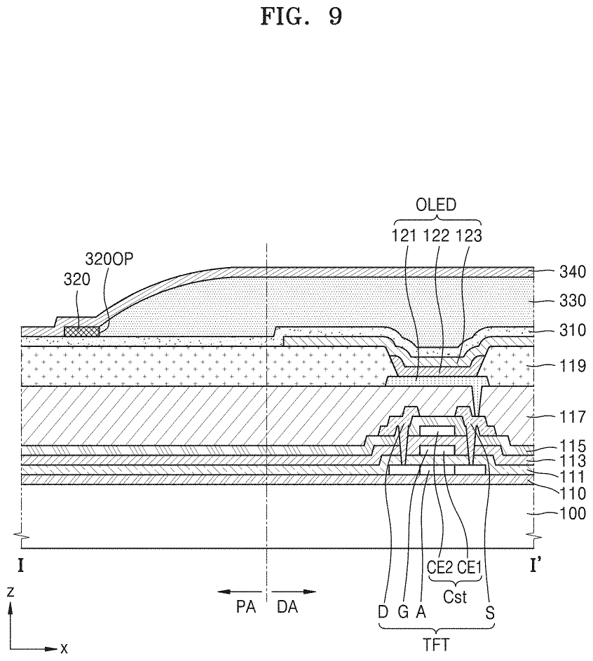

FIG. 9 is a schematic cross-sectional view of a display apparatus according to an embodiment. The embodiment of FIG. 9 is different from that of FIG. 5 in that the first organic layer 320 overlaps the planarization layer 117 and/or the pixel-defining layer 119 in a plan view. In FIG. 9, the same reference numerals as those in FIG. 5 denote like elements, and descriptions thereof will not be repeated.

Referring to FIG. 9, the first organic layer 320 may be arranged in the peripheral area PA. In an embodiment, the first organic layer 320 may be arranged on the first inorganic layer 310. In detail, the first organic layer 320 may be directly on the first inorganic layer 310.

In an embodiment, the first organic layer 320 may overlap at least part of the planarization layer 117 and/or the pixel-defining layer 119 in a plan view. For example, the planarization layer 117 and/or the pixel-defining layer 119 may be arranged in the display area DA and the peripheral area PA, and the first organic layer 320 in the peripheral area PA may overlap at least part of the planarization layer 117 and/or the pixel-defining layer 119 thereunder in a plan view.

In another embodiment, the first organic layer 320 may overlap at least part of the planarization layer 117, but may not overlap the pixel-defining layer 119 in a plan view.

The second organic layer 330 may be arranged on the first inorganic layer 310. In detail, the second organic layer 330 may be arranged directly on the first inorganic layer 310.

In an embodiment, the second organic layer 330 may be arranged in the display area DA, and at least part of the second organic layer 330 may also be arranged in the peripheral area PA. In an embodiment, the second organic layer 330 may overlap at least part of the opening 320OP defined in the first organic layer 320 in a plan view. In an embodiment, the second organic layer 330 may be arranged in the opening 320OP defined in the first organic layer 320.

In an embodiment, the second inorganic layer 340 may be arranged on the first organic layer 320 and the second organic layer 330. In detail, the second inorganic layer 340 may be arranged directly on the first organic layer 320 and the second organic layer 330. In detail, the second inorganic layer 340 may be arranged in the display area DA and the peripheral area PA.

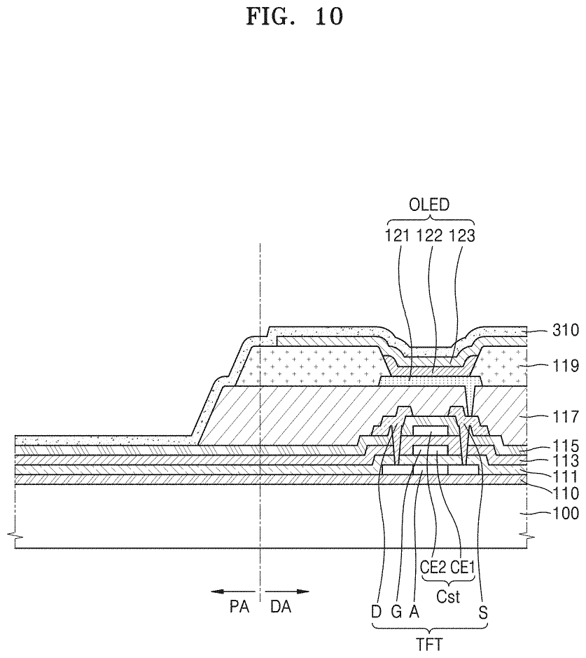

FIGS. 10 to 15 are schematic cross-sectional views of a manufacturing method of a display apparatus, according to an embodiment.

The manufacturing method of the display apparatus is sequentially described with reference to FIGS. 10 to 15.

Referring to FIGS. 10 to 15, the manufacturing method of the display apparatus may include spreading a first organic material 320M on the substrate 100 in the peripheral area PA, forming the first organic layer 320 by hardening the first organic material 320M that is spread, spreading a second organic material 330M on the substrate 100 in the display area DA and the peripheral area PA, and forming the second organic layer 330 by hardening the second organic material 330M. Specifically, the second organic material 330M is spread to the first organic layer 320 in the peripheral area PA from the display area DA.

Referring to FIG. 10, the buffer layer 110 may be formed on the substrate 100. The buffer layer 110 may be formed in the display area DA and the peripheral area PA. The substrate 100 may include glass or polymer resin. A barrier layer (not illustrated) may be further included between the substrate and the buffer layer 110, the barrier layer preventing the penetration of external air.

The thin film transistor TFT may be formed on the buffer layer 110. The thin film transistor TFT may include the semiconductor layer A, the gate electrode G, the source electrode S, and the drain electrode D.

The semiconductor layer A may be formed on the buffer layer 110. The first insulating layer 111 may be formed on the semiconductor layer A. The gate electrode G may be formed on the first insulating layer 111. The second insulating layer 113 may be formed on the gate electrode G, and the upper electrode CE2 may be formed on the second insulating layer 113.

In an embodiment, the lower electrode CE1 may be formed on the first insulating layer 111. The lower electrode CE1 and the upper electrode CE2 may form the storage capacitor Cst. In an embodiment, the lower electrode CE1 and the gate electrode G may be integrally formed. Alternatively, the lower electrode CE1 and the gate electrode G may be separated from each other.

The third insulating layer 115 may be formed on the upper electrode CE2, and the source electrode S and the drain electrode D may be formed on the third insulating layer 115. The planarization layer 117 may be formed on the source electrode S and the drain electrode D. In an embodiment, the planarization layer 117 may be formed in the display area DA, and at least part of the planarization layer 117 may also be formed in the peripheral area PA.

The organic light-emitting diode OLED that is the display element may be formed on the planarization layer 117. The organic light-emitting diode OLED may include the pixel electrode 121 and the opposite electrode 123.

The pixel electrode 121 may be formed on the planarization layer 117, and the pixel-defining layer 119 may be formed on the pixel electrode 121. The pixel-defining layer 119 may define openings through which at least part of the pixel electrode 121 is exposed. In an embodiment, the pixel-defining layer 119 may be formed in the display area DA, and at least part of the pixel-defining layer 119 may also be formed in the peripheral area PA.

The emission layer 122 may be formed on the pixel electrode 121, and the opposite electrode 123 may be formed on the emission layer 122. Although not illustrated, the first functional layer may be formed between the pixel electrode 121 and the emission layer 122, and the second functional layer may be formed between the emission layer 122 and the opposite electrode 123. In an embodiment, the first functional layer and the second functional layer may be collectively referred to as organic functional layers.

The first inorganic layer 310 may be formed on the organic light-emitting diode OLED that is the display element. In an embodiment, the first inorganic layer 310 may be formed in the display area DA and the peripheral area PA. The first inorganic layer 310 may cover the side surface of the planarization layer 117 and the side surface of the pixel-defining layer 119 that are arranged in the peripheral area PA.

In an embodiment, the first inorganic layer 310 and/or the second organic material 330M described below may be hydrophilic. Because the first inorganic layer 310 and/or the second organic material 330M are hydrophilic, the spreadability of the second organic material 330M forming the second organic layer 330 may be improved, and thus, the thickness dispersion of the second organic layer 330 may decrease.

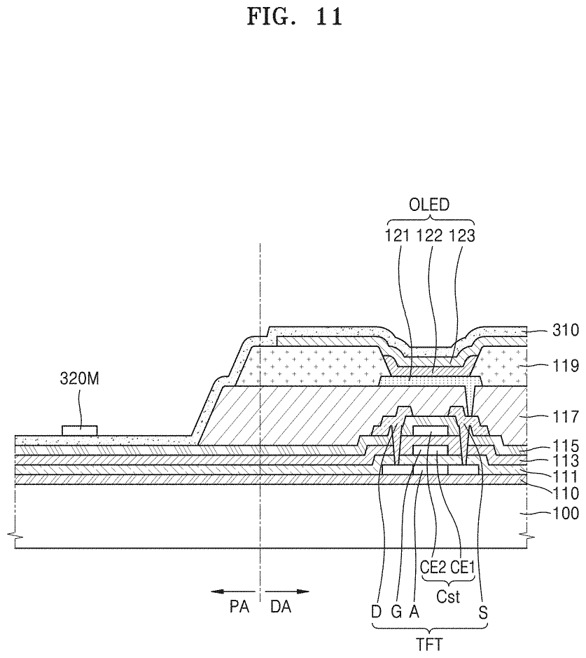

Referring to FIG. 11, after the first inorganic layer 310 is formed in the display area DA and the peripheral area PA, the first organic material 320M may be spread in the peripheral area PA.

In an embodiment, the first organic material 320M may be spread on the first inorganic layer 310 formed in the peripheral area PA. The first organic material 320M may be spread along the periphery of the display area DA.

FIG. 11 illustrates that the first organic material 320M is spread in a rectangular form, but one or more embodiments are not limited thereto. In another embodiment, the first organic material 320M may be spread in different forms such as a trapezoid, a hemisphere, and an oval in a cross-sectional view.

The first organic material 320M may include a polymer-based material. The polymer-based material may include silicon-based resin, acryl-based resin, epoxy-based resin, PI, polyethylene, or the like.

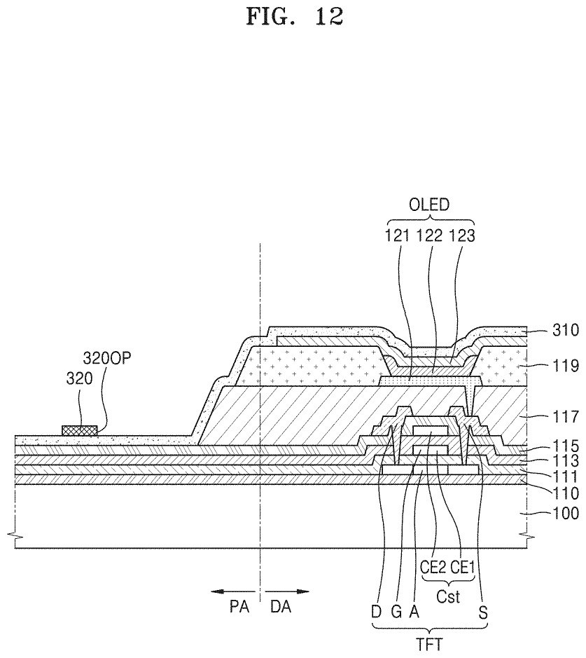

Then, referring to FIG. 12, the first organic layer 320 may be formed by hardening the first organic material 320M.

In an embodiment, the first organic layer 320 may be formed by hardening the first organic material 320M that is spread in the peripheral area PA. In this case, the first organic material 320M may be hardened by using laser or ultraviolet rays utilizing a mask. In an embodiment, the hardened first organic layer 320 may be hydrophobic. Because the hardened first organic layer 320 is hydrophobic, the first organic layer 320 may function as the dam for preventing a loss of the second organic material 330M forming the second organic layer 330.

In an embodiment, the first organic layer 320 may be formed on the first inorganic layer 310. In detail, the first organic layer 320 may be formed directly on the first inorganic layer 310.

The first organic layer 320 may be formed in the peripheral area PA along the periphery of the display area DA. In an embodiment, the first organic layer 320 may define the opening 320OP including the display area DA in a plan view.

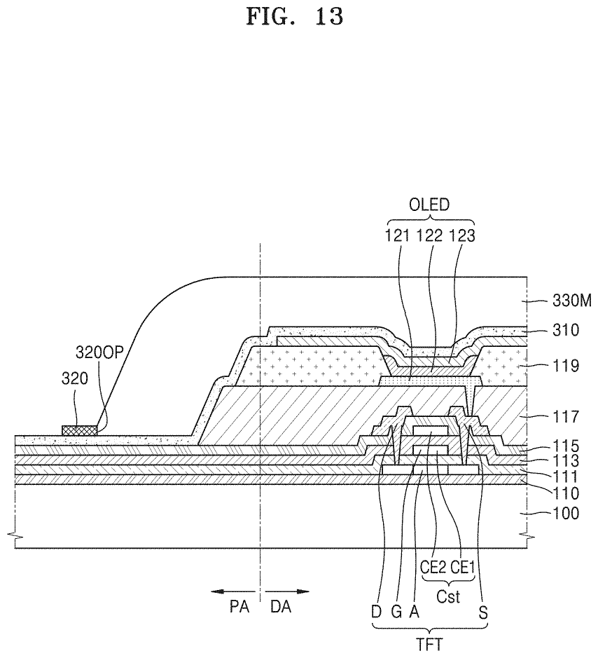

Referring to FIG. 13, after the forming of the first organic layer 320 by hardening the first organic material 320M, spreading the second organic material 330M may be further performed.

In an embodiment, the second organic material 330M may be spread in the display area DA. Also, the second organic material 330M may be spread in at least part of the peripheral area PA. The second organic material 330M may be spread on the first inorganic layer 310. In detail, the second organic material 330M may be spread directly on the first inorganic layer 310.

The second organic material 330M may directly contact the first organic layer 320 and may be spread in the opening 320OP defined in the first organic layer 320. The second organic material 330M may overlap at least part of the opening 320OP defined in the first organic layer 320 in a plan view.

In an embodiment, the second organic material 330M may include the same material as the first organic material 320M. Alternatively, the second organic material 330M may include a different material from the first organic material 320M.

In an embodiment, the second organic material 330M may be hydrophilic. Because the hydrophilic second organic material 330M is spread on the hydrophilic first inorganic layer 310, the spreadability of the second organic material 330M may be improved. Therefore, because the spreadability of the second organic material 330M is improved, the thickness dispersion of the second organic layer 330 described below may decrease.

Also, because the first organic layer 320 is hydrophobic and the second organic material 330M is hydrophilic, the spreadability of the second organic material 330M may be restricted, and thus, a flow of the second organic material 330M towards the outer side of the first organic layer 320 may be effectively prevented or reduced.

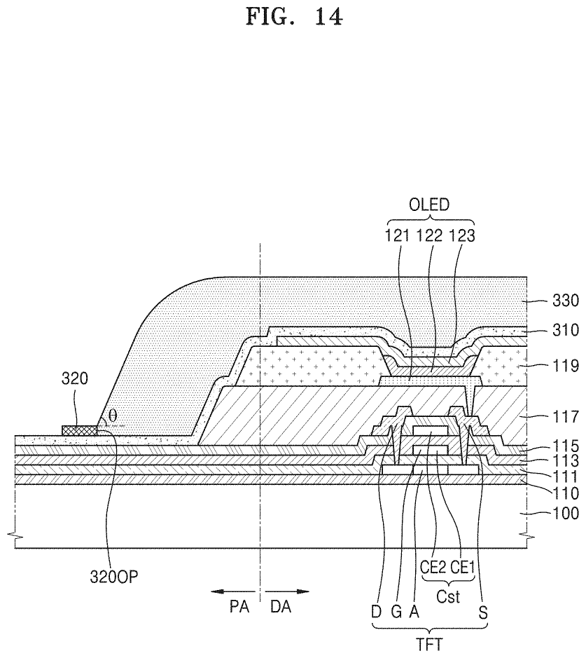

Referring to FIG. 14, after the second organic material 330M is spread in the display area DA and the peripheral area PA, the second organic layer 330 may be formed by hardening the second organic material 330M. In an embodiment, the second organic layer 330 may be formed by hardening the second organic material 330M that is spread in the display area DA and the peripheral area PA, specifically, in the peripheral area PA between the display area DA and the first organic layer 320.

In an embodiment, the second organic layer 330 may be formed on the first inorganic layer 310. In detail, the second organic layer 330 may be formed directly on the first inorganic layer 310.

In an embodiment, the second organic layer 330 may be formed in the display area DA. The second organic layer 330 formed in the display area DA may at least partially overlap the display element (e.g., the organic light-emitting diode OLED) in a plan view.

In an embodiment, the second organic layer 330 may be formed in the display area DA, and at least part of the second organic layer 330 may also be formed in the peripheral area PA. In an embodiment, in the peripheral area PA, the second organic layer 330 may directly contact the first organic layer 320. In an embodiment, the second organic layer 330 may overlap at least part of the opening 320OP defined in the first organic layer 320 in a plan view. In an embodiment, the second organic layer 330 may be formed in the opening 320OP defined in the first organic layer 320.

In an embodiment, the side surface of the second organic layer 330 may have the tilt angle θ that is equal to or greater than about 10 degrees and less than and equal to about 90 degrees. When the tilt angle θ of the side surface of the second organic layer 330 is less than about 10 degrees, the tilt angle θ of the side surface of the second organic layer 330 is too small, and thus, the distance (e.g., the first distance d1, FIG. 5) between the first organic layer 320 and the display area DA may increase so that the size of the peripheral area PA may increase. In this case, because the peripheral area PA corresponds to the non-display area, the increase in the size of the peripheral area PA may indicate that the size of the non-display area increases. On the contrary, when the tilt angle θ of the side surface of the second organic layer 330 is greater than about 90 degrees, the second inorganic layer 340 formed on the second organic layer 330 may be disconnected, and thus, the display element (e.g., the organic light-emitting died OLED) may be damaged by foreign materials or moisture. Therefore, because the tilt angle θ of the side surface of the second organic layer 330 between the first organic layer 320 and the second organic layer 330 is equal to or greater than about 10 degrees and less than or equal to about 90 degrees, the distance between the first organic layer 320 and the display area DA may decrease, and thus, a full-screen display apparatus may be realized (i.e., the peripheral area PA may not be seen substantially to a user in a plan view). At the same time, the damage of the display element (e.g., the organic light-emitting diode OLED) by foreign materials or moisture may be prevented or reduced.

After the first organic material 320M is spread in the peripheral area PA, the first organic layer 320 may be formed by hardening the spread first organic material 320M, and the second organic material 330M may be spread to form the second organic layer 330 in the display area DA and the peripheral area PA, thus preventing or decreasing the loss of the second organic material 330M. In this case, because the first organic layer 320 is hydrophobic and the second organic material 330M forming the second organic layer 330 is hydrophilic, the overflow of the second organic material 330M forming the second organic layer 330 to the outside of the first organic layer 320 may be effectively prevented or reduced. Thus, the second organic layer 330 may be formed between the first organic layer 320 and the display area, in the peripheral area PA.

Because the first organic layer 320 functions as the dam for preventing or reducing the loss of the second organic material 330M forming the second organic layer 330, the size of the peripheral area PA (e.g., the non-display area) may be reduced because of the removal of the dam from the peripheral area PA, and thus, a full-screen display apparatus may be realized. In detail, because the first organic layer 320 functions as the dam for preventing or reducing the loss of the second organic material 330M forming the second organic layer 330, the size of the peripheral area PA (e.g., the non-display area) may be reduced because of the reduction in the minimum distance between the first organic layer 320 and the display area DA, and thus, the full-screen display apparatus may be realized (i.e., the peripheral area PA may not be seen substantially to a user in a plan view).

Although not illustrated, before the second organic layer 330 is formed by hardening the second organic material 330M, planarizing the second organic material 330M may be further performed. As the planarizing of the second organic material 330M is performed, the thickness dispersion of the second organic layer 330 may decrease.

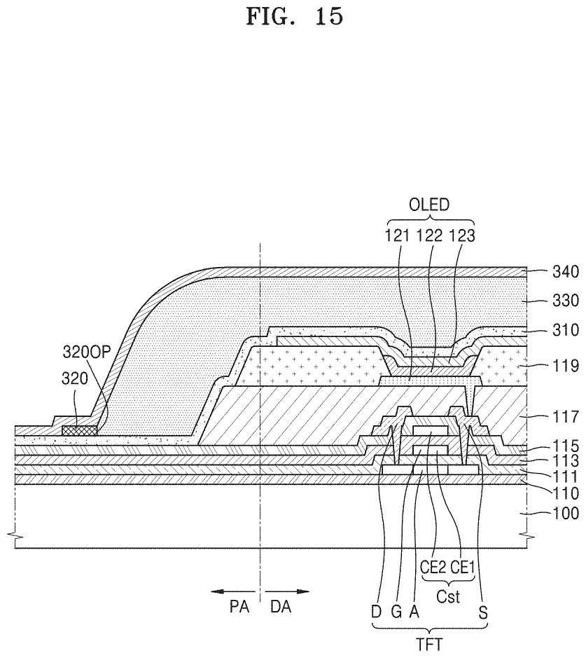

Referring to FIG. 15, after the second organic layer 330 is formed by hardening the second organic material 330M, forming the second inorganic layer 340 on the first organic layer 320 and the second organic layer 330 may be performed.

In an embodiment, the second inorganic layer 340 may be formed in the display area DA and the peripheral area PA. In an embodiment, the second inorganic layer 340 may be formed on the first inorganic layer 310, the first organic layer 320, and the second organic layer 330. In an embodiment, the first inorganic layer 310 and the second inorganic layer 340 may directly contact each other in the peripheral area PA.

In an embodiment, the first organic material 320M may be spread in the peripheral area PA, and the spread first organic material 320M may be hardened, thereby forming the first organic layer 320. In this case, the hardened first organic layer 320 may be spaced apart from the display area DA by a certain distance, and the first organic layer 320 may surround at least part of the display area DA. Then, the second organic material 330M may be spread in the display area DA and the peripheral area PA to the first organic layer 320.

In an embodiment, because the hardened first organic layer 320 may be hydrophobic, the first organic layer 320 in the peripheral area PA may function as the dam for preventing or decreasing the loss of the second organic material 330M that is spread to form the second organic layer 330. In an embodiment, the distance between the first organic layer 320 and the display area DA may be less than the distance between the dam and the display area DA.

Therefore, as the first organic layer 320 is arranged in the peripheral area PA instead of the dam, the size of the peripheral area PA (e.g., the non-display area) may decrease, and the full-screen display apparatus may be realized at the same time (i.e., the peripheral area PA may not be seen substantially to a user in a plan view).

According to the one or more embodiments, a display apparatus, in which a first organic layer arranged along a periphery of a display area prevents or decreases an overflow of an organic material forming a second organic layer towards the outside of the first organic layer, and a manufacturing method of the display apparatus may be realized. However, the scope of the disclosure is not limited by the above effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate comprising a display area and a peripheral area surrounding the display area;
a first organic layer arranged in the peripheral area; and
a second organic layer arranged in the display area and the peripheral area,
wherein a tilt angle of a side surface of the second organic layer is equal to or greater than about 10 degrees and less than or equal to about 90 degrees.

2. The display apparatus of claim 1, wherein the first organic layer directly contacts the second organic layer in the peripheral area.

3. The display apparatus of claim 1, wherein a shape of the first organic layer is a hemisphere or an oval in a cross-sectional view.

4. The display apparatus of claim 1, wherein the first organic layer is arranged along a periphery of the display area.

5. The display apparatus of claim 4, wherein the first organic layer defines an opening covering the display area in a plan view.

6. The display apparatus of claim 5, wherein the second organic layer overlaps at least part of the opening in a plan view.

7. The display apparatus of claim 1, wherein the first organic layer is hydrophobic.

8. The display apparatus of claim 1, further comprising a display element arranged in the display area,
wherein the display element comprises a pixel electrode and an opposite electrode.

9. The display apparatus of claim 8, wherein the second organic layer at least partially overlaps the display element in a plan view.

10. The display apparatus of claim 8, further comprising a first inorganic layer which covers the display element.

11. The display apparatus of claim 10, wherein the first inorganic layer is arranged under the first organic layer and the second organic layer.

12. The display apparatus of claim 10, wherein the first organic layer is arranged directly on the first inorganic layer.

13. The display apparatus of claim 10, wherein the second organic layer is arranged directly on the first inorganic layer.

14. The display apparatus of claim 10, wherein the first inorganic layer is hydrophilic.

15. The display apparatus of claim 10, further comprising a second inorganic layer arranged on the first organic layer and the second organic layer.

16. The display apparatus of claim 15, wherein the first inorganic layer directly contacts the second inorganic layer in the peripheral area.

17. A manufacturing method of a display apparatus comprising a substrate comprising a display area and a peripheral area around the display area, the manufacturing method comprising:
spreading a first organic material on the substrate in the peripheral area;
forming a first organic layer by hardening the spread first organic material;
spreading a second organic material on the substrate in the display area and the peripheral area; and
forming a second organic layer by hardening the second organic material,
wherein a tilt angle of a side surface of the second organic layer is equal to or greater than about 10 degrees and less than or equal to about 90 degrees.

18. The manufacturing method of claim 17, wherein a shape of the first organic layer is a hemisphere or an oval in a cross-sectional view.

19. The manufacturing method of claim 18, wherein the first organic layer directly contacts the second organic layer.

20. The manufacturing method of claim 17, wherein the first organic layer is formed along a periphery of the display area.

21. The manufacturing method of claim 20, wherein the first organic layer defines an opening including the display area therein in a plan view.

22. The manufacturing method of claim 21, wherein the second organic layer overlaps at least part of the opening in the plan view.

23. The manufacturing method of claim 17, wherein the first organic layer is hydrophobic.

24. The manufacturing method of claim 17, further comprising planarizing the spread second organic material after the spreading of the second organic material and before the hardening of the spread second organic material.

25. The manufacturing method of claim 17, further comprising:
before the spreading of the first organic material,
forming a display element on the substrate; and
forming a first inorganic layer on the display element.

26. The manufacturing method of claim 25, wherein the first inorganic layer is hydrophilic.

27. The manufacturing method of claim 25, wherein the first organic layer is formed directly on the first inorganic layer.

28. The manufacturing method of claim 25, wherein the second organic layer is formed directly on the first inorganic layer.

29. The manufacturing method of claim 25, further comprising forming a second inorganic layer on the first organic layer and the second organic layer.

30. The manufacturing method of claim 29, wherein the first inorganic layer directly contacts the second inorganic layer in the peripheral area.
